(19) United States
(12) Patent Application Publication
(10) Pub. No.: US 2025/0020741 A1
(43) Pub. Date: Jan. 16, 2025

(54) MAGNETIC MULTILAYERED STACK BASED ADFMR SENSORS WITH ENHANCED SENSITIVITIES

(71) Applicant: Sonera, Inc., Berkeley, CA (US)

(72) Inventors: Kumar SRINIVASAN, Berkeley, CA (US); Vuk BRAJUSKOVIC, Berkeley, CA (US); Dominic LABANOWSKI, Berkeley, CA (US)

(21) Appl. No.: 18/773,546

(22) Filed: Jul. 15, 2024

Related U.S. Application Data
(60) Provisional application No. 63/513,570, filed on Jul. 14, 2023.

(51) Int. Cl. G01R 33/09; G01R 33/00

(52) U.S. Cl. CPC G01R 33/093; G01R 33/0052

(57) ABSTRACT

Apparatuses (e.g., system and devices, including sensors) and methods that may include single layered or multilayered stack-based acoustically driven ferromagnetic resonance (ADFMR) sensors that incorporate Fe—Ga—B materials (or in some cases Fe—Ga and C, Fe—Si and B, Fe—Si and C, Co—Fe and B, Co—Fe and C) as all or part of the thin-film magnetic element of the ADFMR sensors (e.g., the ferromagnetic film). These apparatuses and methods may have enhanced sensitivities when implemented as part of an ADFMR device. An Fe—Ga—B multilayered thin-film may be, e.g., between about 1 nm-1000 nm in total thickness.

### CLAIM OF PRIORITY

This patent application claims priority to U.S. Provisional Patent Application No. 63/513,570, titled “MAGNETIC MULTILAYERED STACK BASED ADFMR SENSORS WITH ENHANCED SENSITIVITIES,” filed on Jul. 14, 2023, and herein incorporated by reference in its entirety.

### BACKGROUND

An acoustically driven ferromagnetic resonance (ADFMR) sensor may typically include an active sensing element based on a thin-film material system that may include a single layer of a magnetic material that is homogenous in composition across the thickness of the film from bottom to top. An example of such a material system is a thin-film of Fe—Ga—B which constitutes the three elements Fe, Ga and B in a predetermined composition mix. This homogenous thin-film may be prepared via sputter deposition, by two possible routes: from a composite sputter target with a predetermined composition mix, e.g., a composite Fe—Ga—B target, or by co-sputtering a mixture from two or more separate targets, e.g., an Fe—Ga target, and a B target.

However, it would be desirable to enhance the sensitivities of the ADFMR sensors for improved detection. It may also be useful to provide alternative materials and methods of fabricating ADFMR sensors. Described herein are apparatuses (e.g., systems and devices) as well as methods for ADFMR sensors, including sensors having thin-film magnetic materials that may address these needs.

### SUMMARY OF THE DISCLOSURE

The methods and apparatuses described herein may relates generally to the field of sensors, devices and machines based on ferromagnetic resonance that have applications in sensing (e.g., magnetic, geomagnetic, current, location/position, etc.), data storage (e.g., hard-disk drives, magnetic memories, etc.) and energy conversion (e.g. inductors in electric motors), and more specifically to a new and useful system and method for a magnetic thin-film material based on a multilayered stack for application in ADFMR sensors.

For example, described herein are ADFMR apparatuses, comprising: a piezoelectric substrate; at least one input acoustic transducer on the piezoelectric substrate that is configured to activate the piezoelectric element to generate an acoustic wave; a magnetostrictive material on the piezoelectric substrate, wherein the magnetostrictive material comprises a thin film of either Fe—Ga—B or a stack of pairs of Fe—Ga and B layers and wherein the magnetostrictive material is configured to receive and absorb the acoustic wave based on a ferromagnetic resonance of the magnetostrictive material; and at least one output acoustic transducer on the piezoelectric substrate; a readout circuit to detect a change in the acoustic wave to measure an unknown magnetic field to which the magnetostrictive element is exposed.

In any of these apparatuses the magnetostrictive layer may comprise a layer of iron-gallium-boron (Fe—Ga—B). This layer may be a homogenous layer of Fe—Ga—B. Alternatively the magnetostrictive layer may comprise a stack of pairs of Fe—Ga and B layers. For example, the stack of pairs may comprise between about 2 and 30 pairs (e.g., between about 5-15 pairs, between about 5-12 pairs, about 10 pairs, etc.).

In general, the magnetostrictive layer may be between about 10-100 nm thick (e.g., between about 10-50 nm, between about 20-40 nm, between about 10-30 nm thick, etc.).

Any of these apparatuses may include a power source for driving the acoustic energy (e.g., acoustic wave, such as a surface acoustic wave). The power source may be, in some examples, a radio-frequency voltage source electrically connected to the input acoustic transducer. In some cases the acoustic wave may resonate at a ferromagnetic resonance of the magnetostrictive material. The readout circuit may be configured to detect the change in the acoustic wave by detecting one of: an output voltage amplitude, a change in impedance, and/or a reflection of the acoustic wave in the magnetostrictive material.

Any appropriate piezoelectric substrate may be used. For example, the piezoelectric substrate may comprise lithium niobate (LiNbO3).

For example, an acoustically driven ferromagnetic resonance (ADFMR) apparatus, may include: a piezoelectric substrate; at least one input acoustic transducer on the piezoelectric substrate that is configured to activate the piezoelectric element to generate an acoustic wave; a magnetostrictive material on the piezoelectric substrate, wherein the magnetostrictive material comprises a thin film of Fe—Ga—B and wherein the magnetostrictive material is configured to receive and absorb the acoustic wave based on a ferromagnetic resonance of the magnetostrictive material; at least one output acoustic transducer on the piezoelectric substrate; a readout circuit to detect a change in the acoustic wave to measure an unknown magnetic field to which the magnetostrictive element is exposed.

An acoustically driven ferromagnetic resonance (ADFMR) apparatus may include: a piezoelectric substrate; at least one input acoustic transducer on the piezoelectric substrate that is configured to activate the piezoelectric element to generate an acoustic wave; a magnetostrictive material on the piezoelectric substrate, wherein the magnetostrictive material comprises a multilayer stack comprising repeating pairs of Fe—Ga and B layers, and is configured to receive and absorb the acoustic wave based on a ferromagnetic resonance of the magnetostrictive material; and at least one output acoustic transducer on the piezoelectric substrate; a readout circuit to detect a change in the acoustic wave to measure an unknown magnetic field to which the magnetostrictive element is exposed.

Also described herein are methods of forming these magnetostrictive materials. In some cases these methods may be methods for (or part of a method for) forming an acoustically driven ferromagnetic resonance (ADFMR) apparatus, the method may include: sputtering iron, gallium and boron (Fe—Ga—B) into a single layer of magnetostrictive material on a piezoelectric substrate; forming at least one input acoustic transducer and at least one output acoustic transducer on the piezoelectric substrate between the magnetostrictive material; coupling the at least one input acoustic transducer to an energy source configured to drive the at least one input acoustic transducer to apply an acoustic wave to the piezoelectric substrate; and coupling the at least one output acoustic transducer to a readout circuit configured to detect a change in the acoustic wave through the substrate to measure an unknown magnetic field to which the magnetostrictive element is exposed.

Sputtering Fe—Ga—B into a single layer of magnetostrictive material may comprise sputtering to a thickness of between 10-100 nm. Sputtering Fe—Ga—B into a single layer of magnetostrictive material may comprise co-sputtering an iron-gallium (Fe—Ga) sputter target and a boron (B) sputter target. In some examples sputtering Fe—Ga—B into a single layer of magnetostrictive material comprises sputtering from a composite sputter target of Fe—Ga—B. The Sputtering on the piezoelectric substrate may comprise sputtering onto a lithium niobate (LiNbO3) substrate.

The order of any of these steps may be varied. For example, the step of sputtering Fe—Ga—B into a single layer of magnetostrictive material may occur after forming the at least one input acoustic transducer and/or forming the at least one output acoustic transducer, or before.

A method of forming an acoustically driven ferromagnetic resonance (ADFMR) apparatus may include: sputtering pairs of layers of iron-gallium (Fe—Ga) and boron (B) into a multilayer stack of magnetostrictive material on a piezoelectric substrate; forming at least one input acoustic transducer and at least one output acoustic transducer on the piezoelectric substrate between the magnetostrictive material; coupling the at least one input acoustic transducer to an energy source configured to drive the at least one input acoustic transducer to apply an acoustic wave to the piezoelectric substrate; and coupling the at least one output acoustic transducer to a readout circuit configured to detect a change in the acoustic wave through the substrate to measure an unknown magnetic field to which the magnetostrictive element is exposed.

Sputtering pairs of layers of Fe—Ga and B into the multilayer stack of magnetostrictive material may comprise forming the multilayer stack having a thickness of between 10-100 nm. Sputtering pairs of layers of Fe—Ga and B into the multilayer stack of magnetostrictive material may comprise alternating between sputtering an iron-gallium (Fe—Ga) sputter target and a boron (B) sputter target. Sputtering pairs of layers of Fe—Ga and B into the multilayer stack of magnetostrictive material may comprise sputtering between 5-30 pairs of layers of Fe—Ga and B. Sputtering on the piezoelectric substrate may comprise sputtering onto a lithium niobate (LiNbO3) substrate.

As mentioned these steps may be performed in a different order; for example, the step of sputtering the pairs of layers of Fe—Ga and B into the multilayer stack of magnetostrictive material may be performed after forming the at least one input acoustic transducer and/or the output acoustic transducer.

Any of these apparatuses and method may, instead of using Fe—Ga and B alloy(s), be used with Fe—Ga and C, Fe—Si and B, Fe—Si and C, Co—Fe and B, Co—Fe and C, Co—Ga and B, Co—Ga and C, or any combinations thereof (i.e. Fe—Ga and B and Co—Ga and B or Fe—Co—Ga and B).

All of the methods and apparatuses described herein, in any combination, are herein contemplated and can be used to achieve the benefits as described herein.

### BRIEF DESCRIPTION OF THE DRAWINGS

A better understanding of the features and advantages of the methods and apparatuses described herein will be obtained by reference to the following detailed description that sets forth illustrative embodiments, and the accompanying drawings of which:

FIG. 1A is an example of a single-layered Fe—Ga—B thin film.

FIGS. 1B-1C illustrate examples of VNA-FMR polar absorption (FIG. 1B) and derivate (FIG. 1C) scans for the single-layered Fe—Ga—B thin film of FIG. 1A.

FIG. 1D is an example of a multi-layered thin-film stack of alternating FeGa and B layers.

FIGS. 1E and 1F illustrate examples of VNA-FMR polar absorption (FIG. 1E) and derivate (FIG. 1F) scans for the multi-layered thin-film stack of alternating FeGa and B layers of FIG. 1D.

FIGS. 2A-2B shows graphs illustrating the angular dependence of resonance fields (FIG. 2A) and resonance linewidths (FIG. 2B) of single-layered and multi-layered thin-films stacks of Fe—Ga—B.

FIG. 3A illustrates a single-layered Fe—Ga—B thin film.

FIGS. 3B-3D show examples of ADFMR polar absorption and derivate scans for the single-layered Fe—Ga—B thin film of FIG. 3A.

FIG. 3E illustrates a multi-layered thin-film stack of alternating FeGa and B layers.

FIGS. 3F-3H show examples of ADFMR polar absorption and derivate scans for the multi-layered thin-film stack of alternating FeGa and B layers of FIG. 3E.

FIG. 4A is an example of a single-layered Fe—Ga—B thin film.

FIGS. 4B and 4C shows examples of selected ADFMR line scans from the single-layered Fe—Ga—B thin film of FIG. 4A.

FIG. 4D is an example of a multi-layered thin-film stack of alternating FeGa and B layers.

FIGS. 4E and 4F shows examples of selected ADFMR line scans from the multi-layered thin-film stack of alternating FeGa and B layers of FIG. 4D.

FIGS. 5A and 5B show exemplary X-TEM images from a single-layered Fe—Ga—B thin film (FIG. 5A) and a multi-layered thin-film stack of alternating FeGa and B layers (FIG. 5B).

FIG. 6 schematically illustrates an example of a method for producing single-layer Fe—Ga—B thin film on substrate (e.g., piezoelectric substrate, such as a piezoelectric on insulator (POI) substrate)

FIG. 7 schematically illustrates an example of a method variation for producing single-layer Fe—Ga—B thin film on patterned delay-line LiNbO3 substrates (ADFMR devices).

FIG. 8 schematically illustrates an example of a method for producing multi-layered Fe—Ga/B thin film on substrates.

FIG. 9 schematically illustrates an example of a method for producing multi-layered Fe—Ga/B thin film on patterned delay-line LiNbO3 substrates (ADFMR devices).

FIG. 10 is a schematic representation of a single-layered Fe—Ga—B thin film prepared on LiNbO3 substrate (both free-standing and patterned delay-line ADFMR devices).

FIG. 11 is a schematic representation of multilayered Fe—Ga/B thin film prepared on LiNbO3 substrate (both free-standing and patterned delay-line ADFMR devices).

FIG. 12 schematically illustrates one example of an ADFMR apparatus incorporating an Fe—Ga—B single-layer film or multilayer film.

### DETAILED DESCRIPTION

Acoustically driven ferromagnetic resonance (ADFMR) sensor may be used as field sensors by measuring transmitted power, among many other applications. The sensor may include an acoustic drive portion consisting of one of many different types of acoustic resonators, including surface acoustic wave (SAW) resonators, film bulk acoustic resonators (FBAR), and bulk acoustic resonators (e.g., high-tone bulk acoustic resonators, HBAR). The acoustic drive portion may generate an acoustic wave at or near the ferromagnetic resonance of a magnetostrictive element. The acoustic drive portion may include one or more (e.g., a pair of) transducers, such as electrodes, that activate a piezoelectric element to generate acoustic waves. The magnetostrictive element receives the wave as a signal and changes its properties in response to the received wave. Detection circuitry detects the change in the property of the magnetostrictive element and that change is used to determine a result. The detection circuitry may also measure the change in the wave generated by the acoustic drive portion.

Thus, in some examples, a single or array ADFMR sensor unit may include: a piezoelectric substrate comprising the main body of the ADFMR sensor component; an input interdigitated transducer (IDT), that generates a surface acoustic wave (SAW) from an electric signal using the piezoelectric effect which propagates along the substrate; a ferromagnetic film, along the substrate that enables absorption of magnetic fields by the SAW as it propagates thereby modifying the SAW; and an output IDT, that converts the modified SAW to an electric signal. This modified SAW may then be used to determine the strength of the magnetic field. The ADFMR sensor may have many variations that include one, or multi-sensing capabilities.

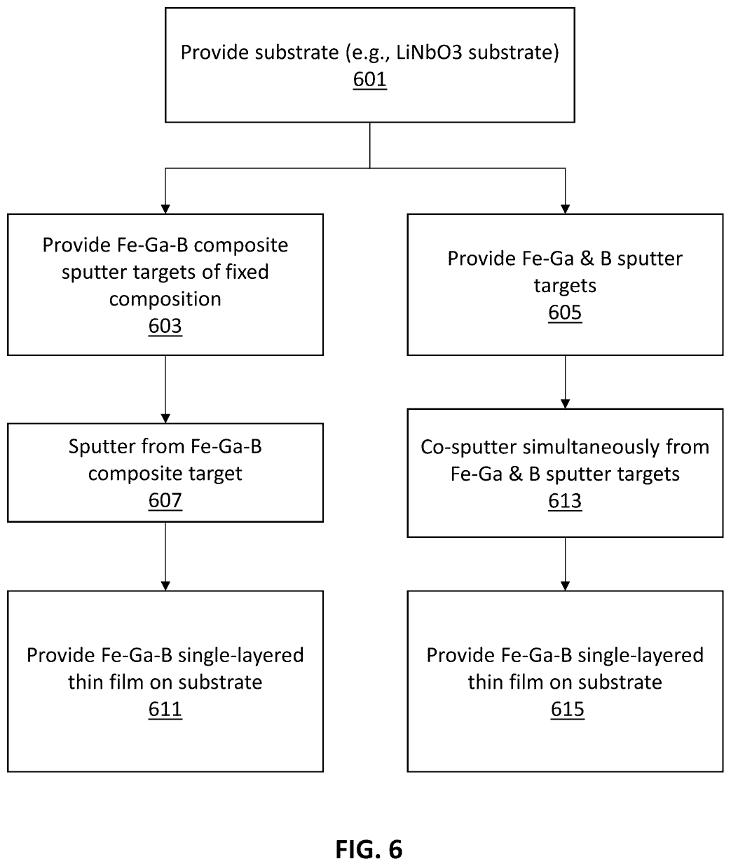

Described herein are apparatuses (e.g., system and devices, including sensors) and methods that may include multilayered stack-based acoustically driven ferromagnetic resonance (ADFMR) sensors that incorporate Fe—Ga—B materials (or in some cases Fe—Ga and C, Fe—Si and B, Fe—Si and C, Co—Fe and B, Co—Fe and C) as all or part of the thin-film magnetic element of the ADFMR sensors (e.g., the ferromagnetic film). These apparatuses and methods may have enhanced sensitivities when implemented as part of an ADFMR device. An Fe—Ga—B multilayered thin-film may be, e.g., between about 1 nm-1000 nm (e.g., between 1 nm-500 nm, 1 nm-100 nm, 10 nm-100 nm, 1 nm-10 nm, 10 nm-100 nm, 100 nm-1000 nm, etc. in total thickness. These apparatuses and methods may be implemented (e.g., fabricated) as described in FIGS. 6-11, described in greater detail below.

In one example, the apparatuses and methods may employ a multi-layer Fe—Ga—B stack including alternating repeats of very thin individual layers of Fe—Ga and B. This may be referred to as a multi-layer stack; this multi-layer stack may be prepared by alternatively sputtering from two separate targets of Fe—Ga and B. Compared to the single-layered, homogenous Fe—Ga—B thin-film material at the same total thickness, the multi-layered Fe—Ga—B thin-film material variation may show lower FMR linewidths and enhanced slopes/sensitivities in ADFMR devices. Accordingly, the multi-layered material stack design of the system and method may improve ADFMR sensor performance.

In some examples, Fe—Ga—B thin films of ˜20 nm thickness may be sputtered deposited on LiNbO3 substrates (either bare substrates or patterned ADFMR devices). Fe—Ga—B film stacks may be prepared via simultaneous co-sputter of Fe—Ga and B, to produce a homogenous film. Alternatively or additionally, Fe—Ga—B film stacks may be prepared via alternating sputter deposition of Fe—Ga and B to produce a multi-layered stack. In an exemplary implementation of the latter, the basis sequence (e.g., repeating unit) may include Fe—Ga (˜1 nm)/B (˜1 nm) layer, and this basis may be repeated a number, e.g., x, of times (e.g., 2 times, 3 times, 4 times, 5 times, 6 times, 7 times, 8 times, 9 time, 10 times, 11 times, 12, times, 15 times, 5 or more times, 7 or more times, 10 or more times, etc.) for a total stack thickness of ˜20 nm. These indicated layer thickness are used for illustrative purposes only and the apparatuses and methods described herein are not intended to be limited to these exemplary layer thicknesses.

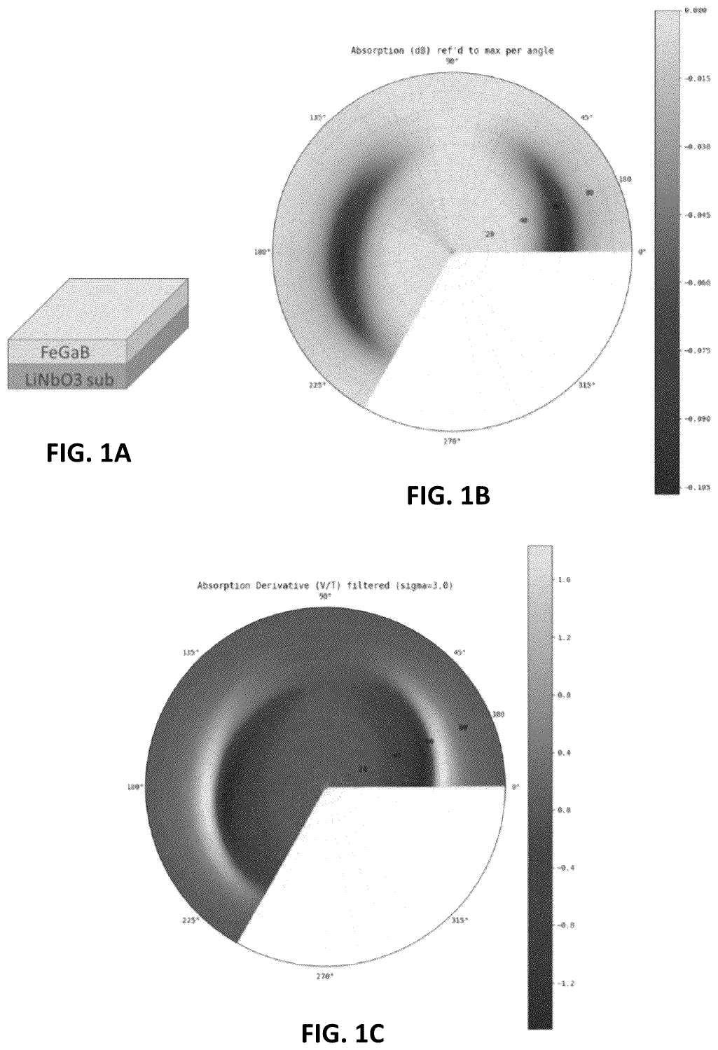

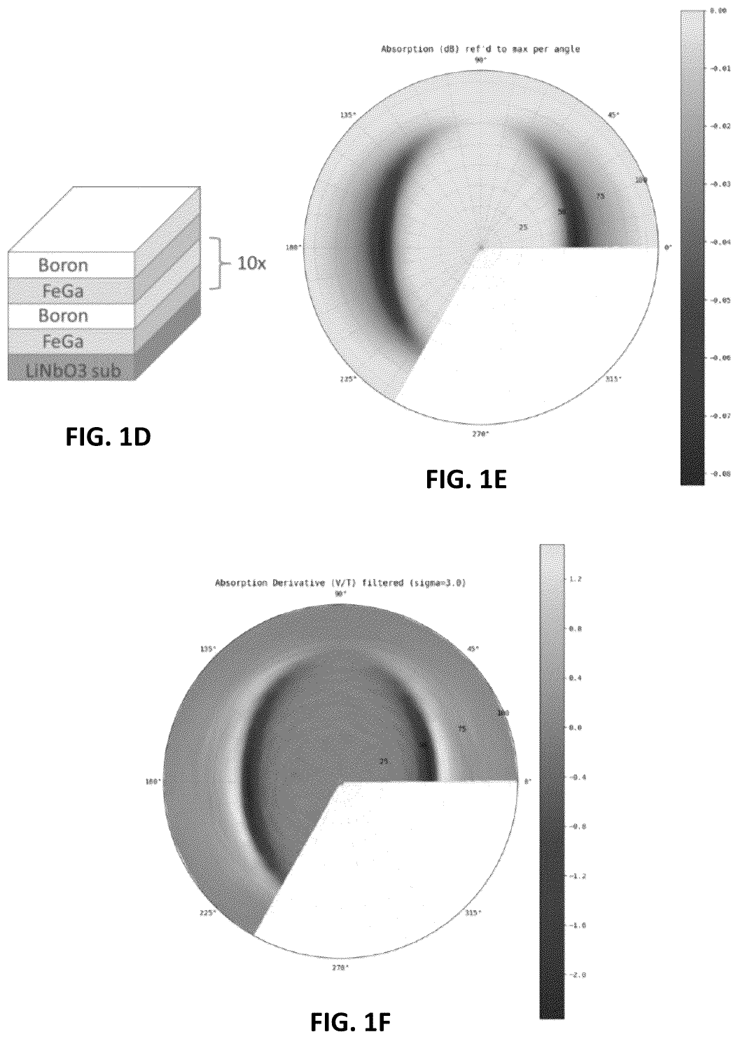

FIGS. 1A-1C and 1D-1F show examples of vector network analyzer-Ferromagnetic Resonance (VNA-FMR) absorption polar scans alongside the derivative scans, obtained respectively from the single-layered (FIGS. 1A-1C) and the multi-layered (FIGS. 1D-1F) Fe—Ga—B films, sputtered on bare LiNbO3 substrates. FIG. 1A shows a schematic of a single-layered Fe—Ga—B film. The VNA-FMR polar absorptions for a single-layered Fe—Ga—B thin film prepared by simultaneous co-sputter of Fe—Ga and B is shown in FIG. 1B as a heat map. FIG. 1C shows a heat map of the absorption derivative for the same example.

FIG. 1D shows an example of a multi-layered thin-film stack of alternating FeGa and B layers prepared by alternating sputter deposition of Fe—Ga and B. FIGS. 1E-1F illustrate VNA-FMR polar absorption for such a multi-layered thin-film stack. The absorption profiles appear similar in shape (anisotropy) and extent (location of FMR field). The band of absorption which corresponds to the FMR linewidth, appears slightly narrower for the multi-layer film compared to the single-layered film.

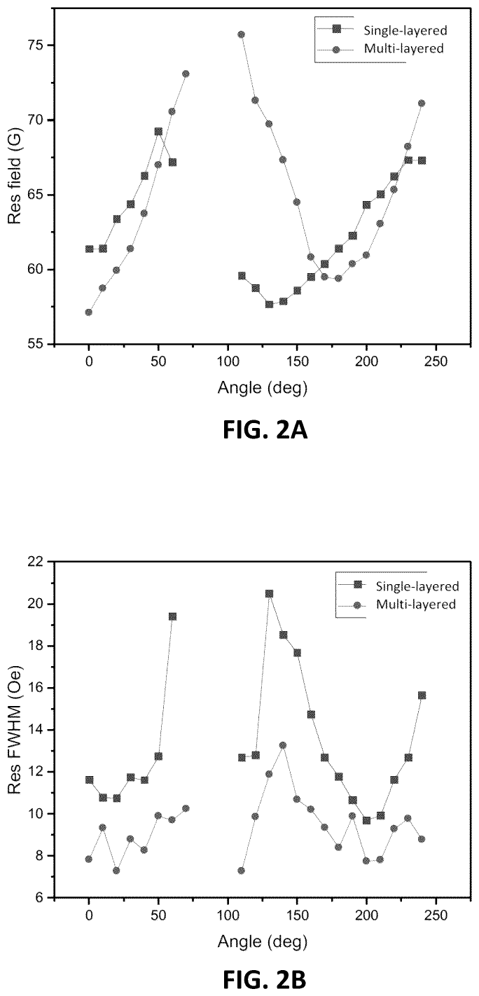

FIGS. 2A and 2B show the angular dependence of the FMR fields and linewidths of the two Fe—Ga—B films, extracted from the polar absorption scans shown in FIGS. 1B-1C and 1E-1F. While the FMR field plotted in FIG. 2A appears to follow a different angular dependence in the two cases, indicating a change in anisotropy, the range of the FMR fields overlap. However, the FMR linewidths, plotted in FIG. 2B, are noticeably smaller for the multi-layered film stack compared to the single-layered film stack.

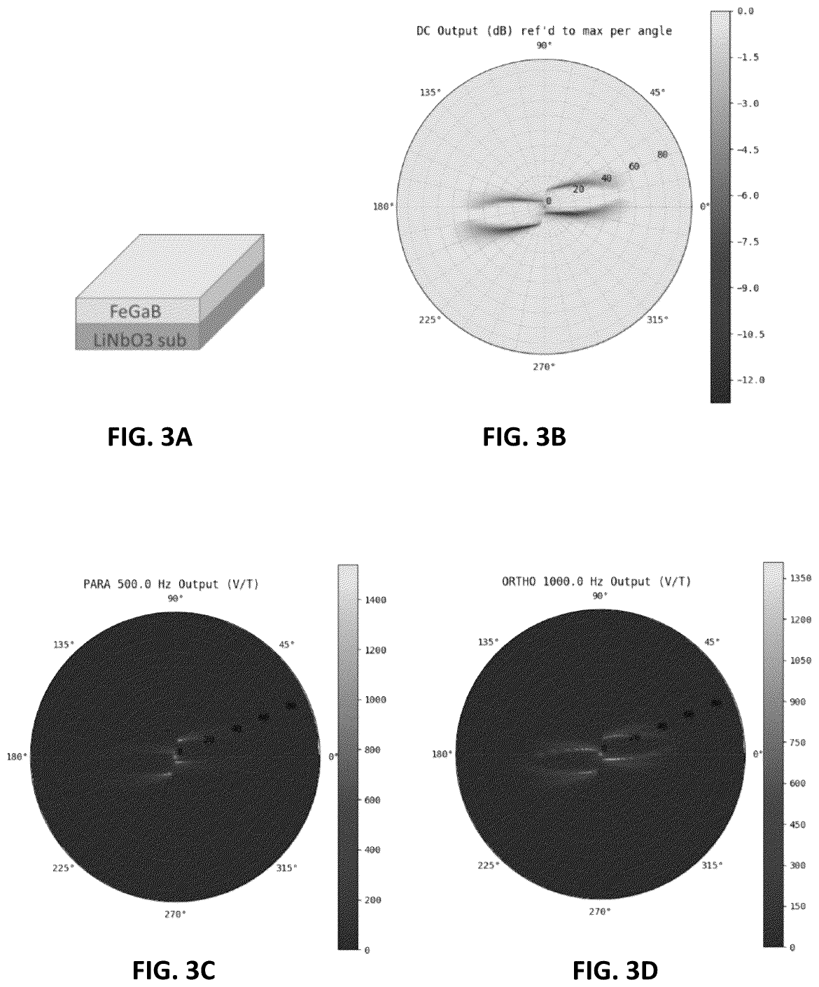

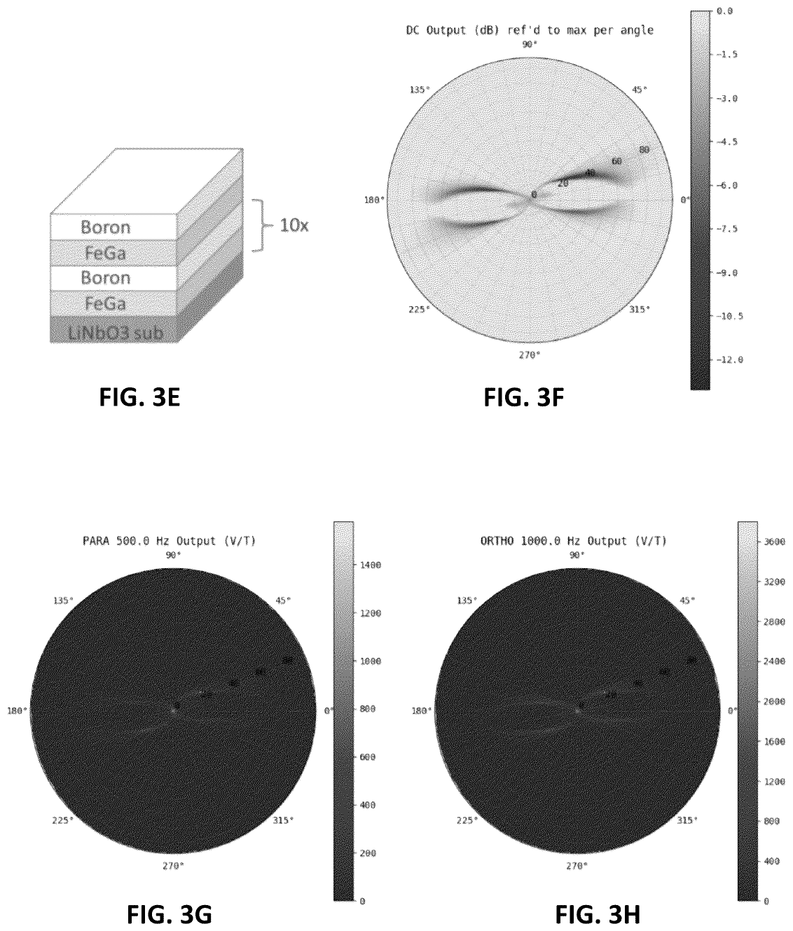

FIGS. 3A-3D and 3E-3H show the ADFMR absorption polar scan alongside the parallel & orthogonal derivative scans obtained on an IQ mixer setup, respectively from the single-layered and the multi-layered Fe—Ga—B films which were sputtered on patterned ADFMR devices. In both cases, the polar scans show four lobes of absorption peaking at about 12 dB. However, while the parallel derivative slopes are similar in the two cases, peaking at ˜1400 V/T, the orthogonal derivative slopes are much higher for the multi-layer film stack, peaking at ˜3600 compared to ˜1350 for the single-layered film stack.

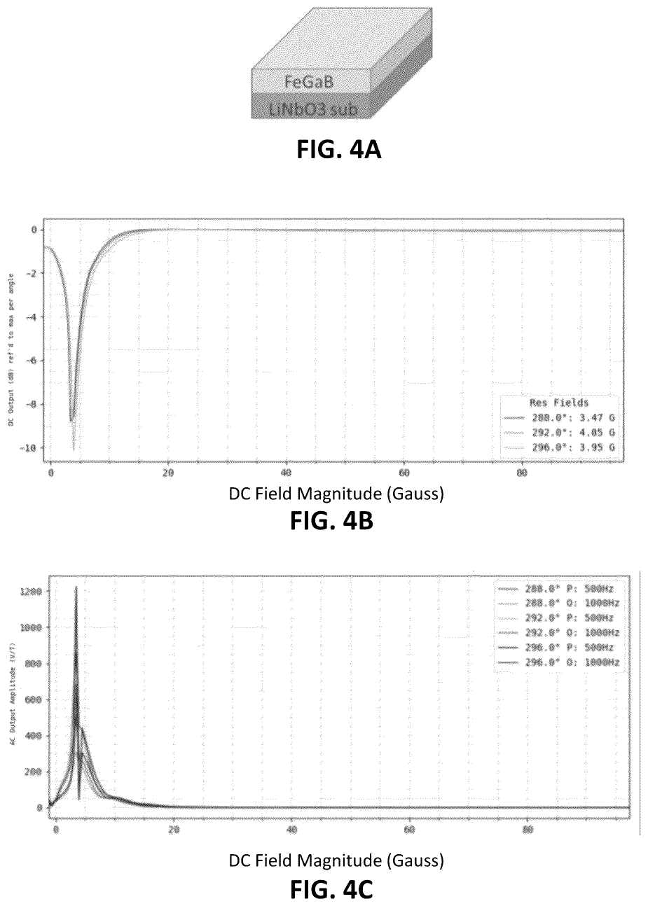

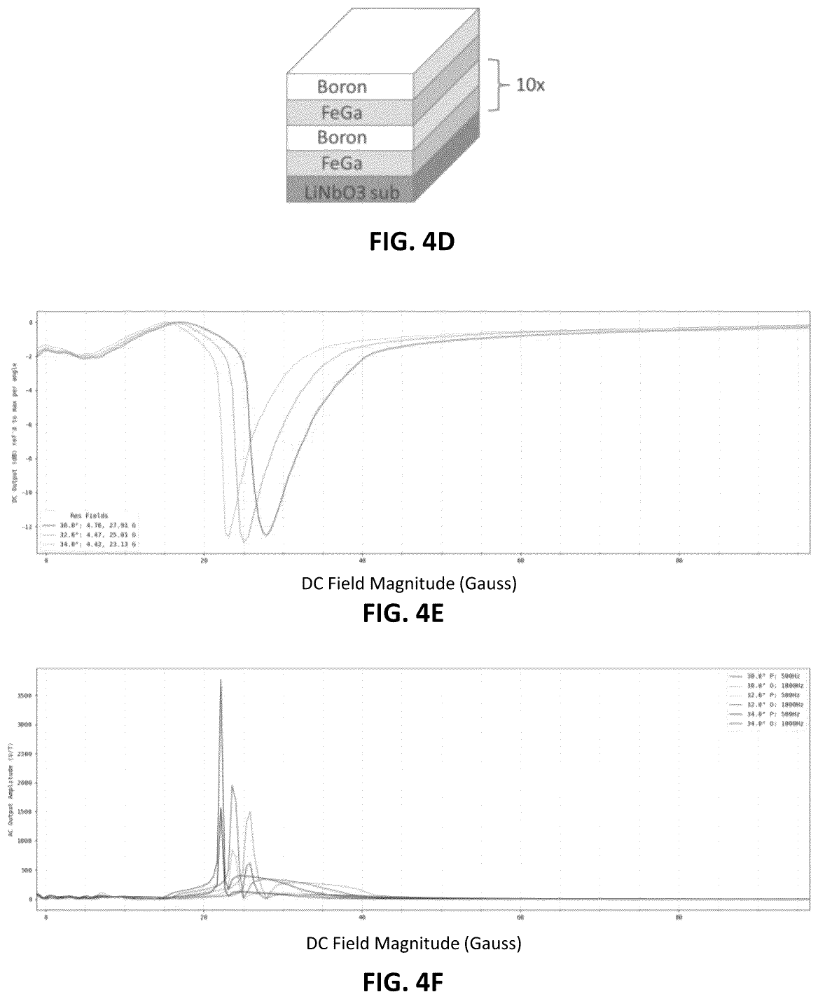

This aspect is further examined in FIGS. 4A-4C and 4D-4F which show plots of line-cut scans from selected angles for the two types of thin-film stacks. In particular, FIGS. 4B-4C shows selected line-cut plots from ADFMR scans acquired on an IQ mixer setup, indicating the field-dependency of power absorption (FIG. 4B) and parallel/orthogonal derivates (FIG. 4C), from a single-layered thin film of homogeneous Fe—Ga—B (FIG. 4A). Similarly, the field-dependency of power absorption is shown in FIG. 4E and the parallel/orthogonal derivates are shown in FIG. 4F for a multi-layered thin-film stack of alternating Fe—Ga and B layers (e.g., FIG. 4D). For the single-layered Fe—Ga—B thin film stack, such as the example shown in FIG. 4A, the line scans in the angular range from 288° to 2960 showing Gaussian (or Lorentzian) shaped ADFMR absorption curves peaking at ˜4G (0.4 mT) and V/T derivative slopes peaking at ˜1200. For the multi-layered Fe—Ga—B thin film stack, such as the example shown in FIG. 4D, the ADFMR absorption curves exhibit a distinct log-normal type of curve with a skew to the right. At 34°, this curve peaks at a field of ˜23G (2.3 mT). While the parallel V/T derivative scan at this angle peaks at ˜1500, the orthogonal scan reaches a max value of ˜3600.

The multi-layered thin-film stack design proposed here may be for use in the magnetic sensing element of ADFMR devices, or as the sensing element of FMR devices, more generally. The variations of material system described herein are primarily used as an example, the design approach of these systems and methods may be applied to other material systems to produce similar multi-layered stacks. Examples of other material systems are Fe—Ga and C, Fe—Si and B, Fe—Si and C, Co—Fe and B, Co—Fe and C, Co—Ga and B, Co—Ga and C, or any combinations thereof (i.e., Fe—Ga and B and Co—Ga and B or Fe—Co—Ga and B), etc.

Besides sputtering, other thin-film deposition techniques such as pulsed laser deposition (PLD), e-beam evaporation, and the like, can be used for preparing the magnetic thin-film sensing element of ADFMR sensors.

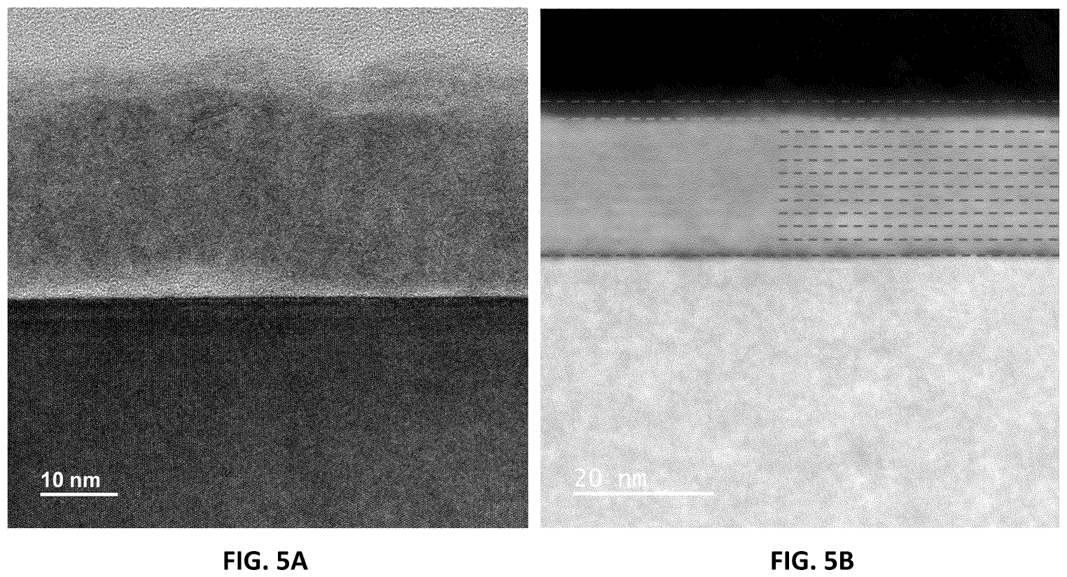

In general, the alternate sputtering of Fe—Ga and B layers of the system and method may produce a thin-film stack that alternates in composition distribution between the Fe—Ga and B constituents. This microstructural feature is revealed by TEM scans. FIGS. 5A and 5B show cross-sectional TEM scans obtained from the single-layered and multi-layered Fe—Ga—B film stacks respectively. FIG. 5A shows an exemplary cross-sectional TEM scan of a single-layered Fe—Ga—B thin film prepared by simultaneous co-sputter of Fe—Ga and B. FIG. 5B shows an exemplary cross-sectional TEM scan of a multi-layered thin-film stack of alternating Fe—Ga and B layers prepared by alternating sputter deposition of Fe—Ga and B. While the single-layered film displays a homogenously distributed thin-film layer, the multi-layered film displays distinct layers of alternating contrast, as shown by the dashed lines.

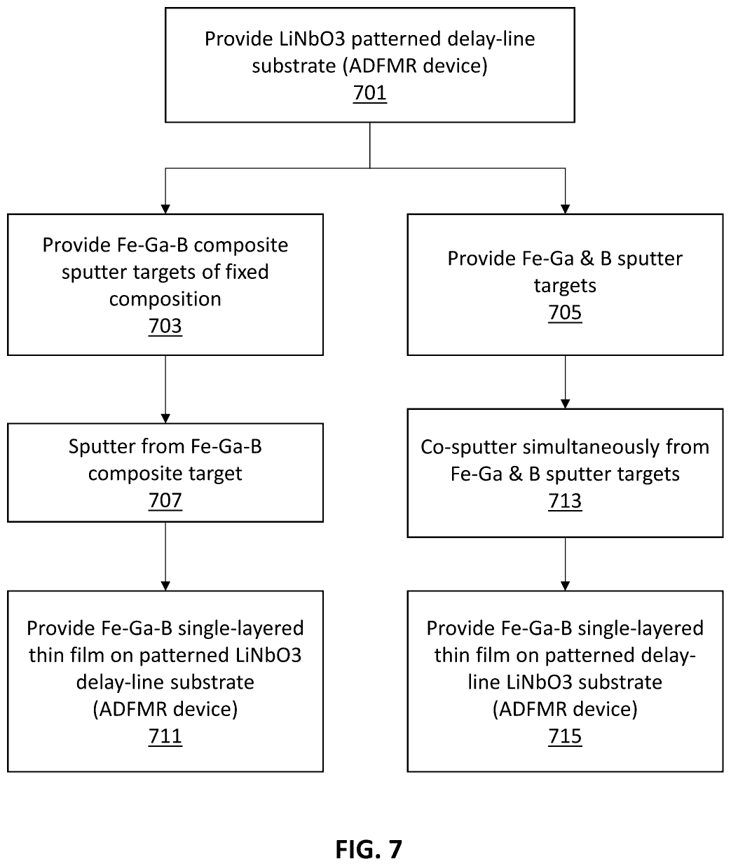

Any appropriate fabrication technique may be used to form these magnetic (magnetostrictive) films. For example, FIGS. 6-7 illustrate methods of forming single-layer films of Fe—Ga—B. Any appropriate substrate may be used. In any of these apparatuses and methods the substrate may be a piezoelectric substrate. In some cases the substrate may be a piezoelectric on insulator (POI), e.g., using LiNbO3, where the LiNbO3 is attached to a carrier wafer for easier handling. FIG. 6 describes a “free standing” magnetic film, whereas FIG. 7 shows the fabrication of the magnetic film as part of an ADFMR apparatus. In FIG. 6, the method may include providing (or accessing) a substrate, such as LiNbO3 601, then either sputtering from a composite sputtering target of the Fe—Ga—B 605 (which is accessed or provided 603 as part of the method), or co-sputtering simultaneously from separate Fe—Ga and B sputter targets 613 (which are accessed or provided 603 as part of the method). In both cases the results provide a Fe—Ga—B single-layered thin film on the substrate 611, 615.

In FIG. 7 the same method may be used but with an ADFMR substrate, in which the substrate is patterned as a delay line substrate. Thus, the method may include providing (or accessing) a substrate, such as LiNbO3 701 patterned as a delay-line substrate, then either sputtering from a composite sputtering target of the Fe—Ga—B 705 (which is accessed or provided 703 as part of the method), or co-sputtering simultaneously from separate Fe—Ga and B sputter targets 713 (which are accessed or provided 703 as part of the method). In both cases the results provide a Fe—Ga—B single-layered thin film on the ADFMR piezoelectric substrate 711, 715. In any of these methods, the pattern may be patterned by photolithography and/or liftoff; any appropriate patterning techniques may be used.

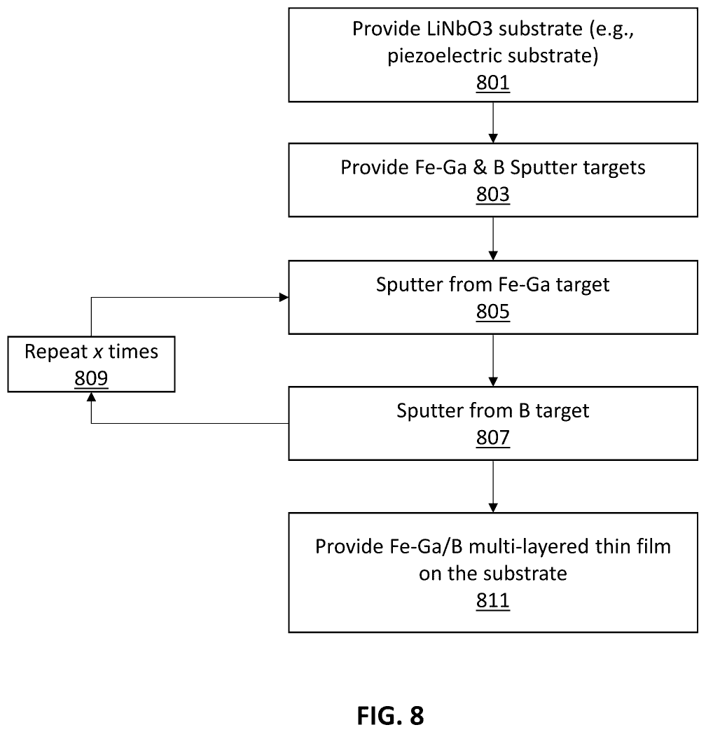

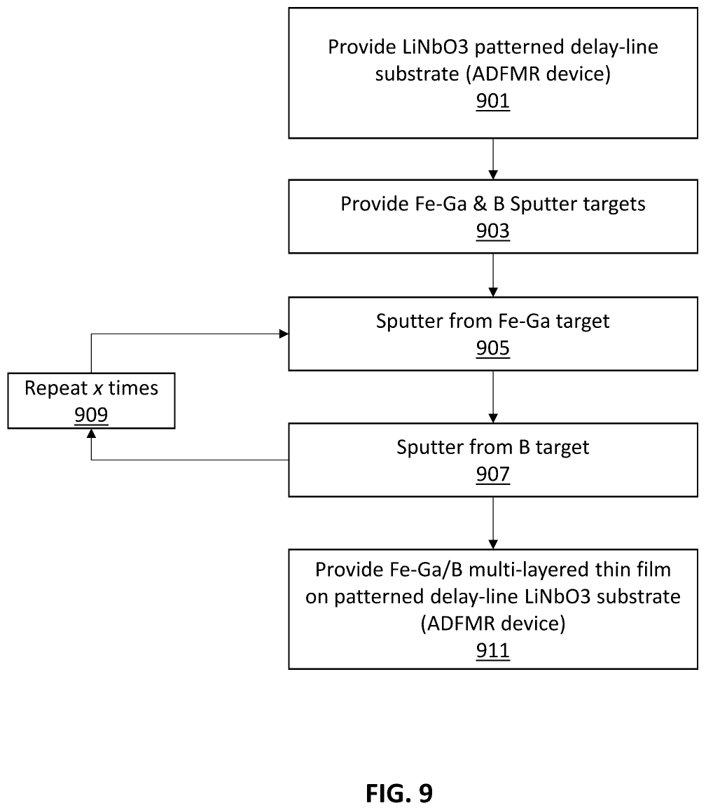

FIGS. 8 and 9 illustrate methods of forming magnetic (magnetostrictive) films comprising multilayered stacks. In FIG. 8, the method includes accessing or providing the substrate, in this example a ‘free-standing’ substrate (e.g. not part of, or not yet part of, an ADFMR apparatus) 801, then providing or accessing separate Fe—Ga and B sputter targets 803. The method may then iteratively sputter pairs of Fe—Ga and B layers, e.g., by sputtering from the Fe—Ga sputter target 805, then sputtering from the B sputter target 807 (or vice versa). These steps may be repeated multiple times (e.g., x times) 809 to form the desired number of layers (or pairs of layers). The result provides and Fe—Ga/B multilayered stack forming a thin film on the piezoelectric substrate 811.

FIG. 9 illustrates the same general technique for forming the multilayered stack as part of an ADFMR apparatus. In this case the substrate provided (or accessed) may be a piezoelectric (e.g., LiNbO3) substrate that is patterned as a delay-line substrate 901, then providing or accessing separate Fe—Ga and B sputter targets 903. The method may then iteratively sputter pairs of Fe—Ga and B layers, e.g., by sputtering from the Fe—Ga sputter target 905, then sputtering from the B sputter target 907 (or vice versa). These steps may be repeated multiple times (e.g., x times) 909 to form the desired number of layers (or pairs of layers). The result provides and Fe—Ga/B multilayered stack forming a thin film on the piezoelectric substrate 911 for the ADFMR apparatus.

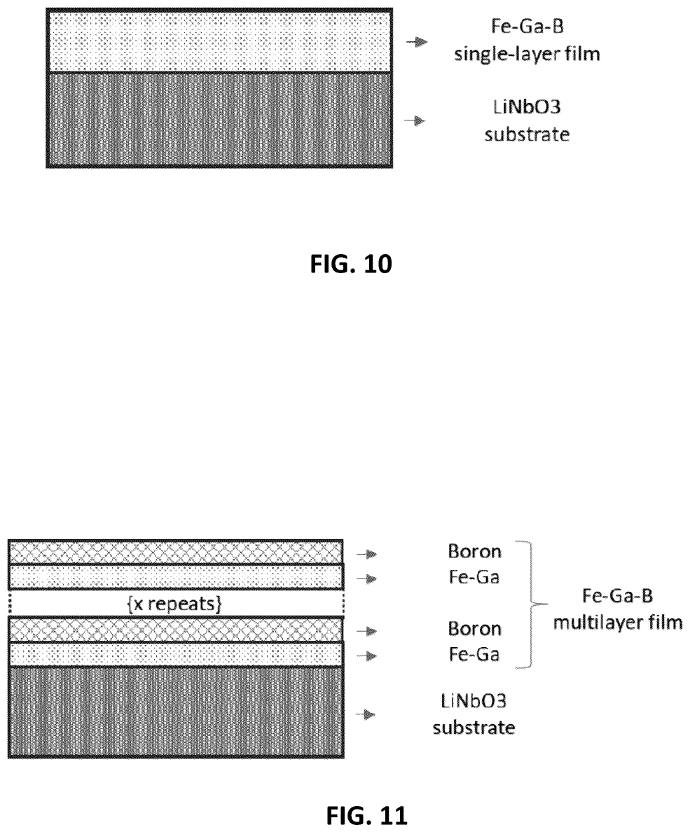

FIGS. 10 and 11 show examples of the resulting magnetic films (not to scale). In FIG. 10 the single layer film of Fe—Ga—B is shown atop a piezoelectric substrate of LiNbO3. In FIG. 11, the magnetic film is a multilayer film of Fe—Ga—B formed of pairs of Fe—Ga and B stacked atop each other on top of the substrate (LiNbO3) layer.

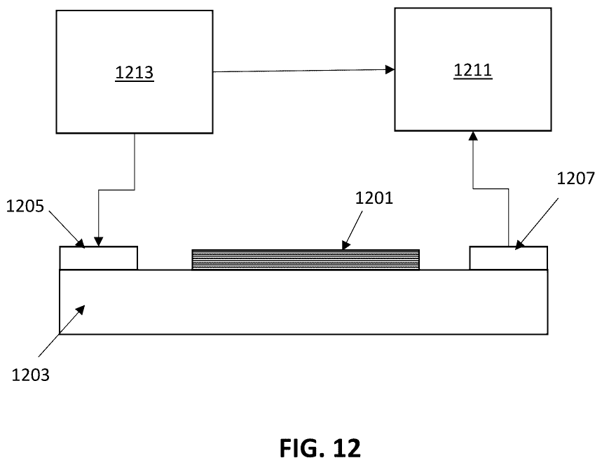

FIG. 12 shows a schematic example of an ADFMR apparatus (e.g., sensor) configured to include either an Fe—Ga—B single film or a multi-layer Fe—Ga/B stack as the magnetostrictive material forming a portion of the sensor. In FIG. 12, the apparatus includes a piezoelectric substrate 1203. Any appropriate piezoelectric material may be used, including but not limited to LiNbO3. The apparatus may generally include at least one input acoustic transducer 1205 on the piezoelectric substrate. The acoustic transducer is configured to activate the piezoelectric element to generate an acoustic wave. In any of these apparatuses the input acoustic transducer 1205 may be interdigitated transducers with electrodes that are configured to excite surface acoustic waves (SAWs). The input acoustic transducer may be coupled (e.g., electrically coupled to the source of input energy 1213, such as a radio-frequency (RF) voltage source, to drive the application of acoustic energy through the device. The apparatus may also include at least one output acoustic transducer 1207 on the piezoelectric substrate. The output acoustic transducer may be similar to the input acoustic transducer. The output acoustic transducer 1207 may electrically couple to the readout 1211, e.g., readout circuitry that is configured to detect a change in the acoustic wave to measure an unknown magnetic field to which the magnetostrictive element is exposed.

In any of these examples, as described above, the magnetostrictive material 1201 on the piezoelectric substrate may be as described above: a thin film of either Fe—Ga—B, or a multilayer stack of pairs of Fe—Ga and B layers. The magnetostrictive material is generally configured to receive and absorb the acoustic wave based on a ferromagnetic resonance of the magnetostrictive material.

All publications and patent applications mentioned in this specification are herein incorporated by reference in their entirety to the same extent as if each individual publication or patent application was specifically and individually indicated to be incorporated by reference. Furthermore, it should be appreciated that all combinations of the foregoing concepts and additional concepts discussed in greater detail below (provided such concepts are not mutually inconsistent) are contemplated as being part of the inventive subject matter disclosed herein and may be used to achieve the benefits described herein.

Any of the methods (including user interfaces) described herein may be implemented as software, hardware or firmware, and may be described as a non-transitory computer-readable storage medium storing a set of instructions capable of being executed by a processor (e.g., computer, tablet, smartphone, etc.), that when executed by the processor causes the processor to control perform any of the steps, including but not limited to: displaying, communicating with the user, analyzing, modifying parameters (including timing, frequency, intensity, etc.), determining, alerting, or the like. For example, any of the methods described herein may be performed, at least in part, by an apparatus including one or more processors having a memory storing a non-transitory computer-readable storage medium storing a set of instructions for the processes(s) of the method.

When a feature or element is herein referred to as being “on” another feature or element, it can be directly on the other feature or element, or intervening features and/or elements may also be present. In contrast, when a feature or element is referred to as being “directly on” another feature or element, there are no intervening features or elements present. It will also be understood that, when a feature or element is referred to as being “connected”, “attached” or “coupled” to another feature or element, it can be directly connected, attached or coupled to the other feature or element or intervening features or elements may be present. In contrast, when a feature or element is referred to as being “directly connected”, “directly attached” or “directly coupled” to another feature or element, there are no intervening features or elements present. Although described or shown with respect to one embodiment, the features and elements so described or shown can apply to other embodiments. It will also be appreciated by those of skill in the art that references to a structure or feature that is disposed “adjacent” another feature may have portions that overlap or underlie the adjacent feature.

Terminology used herein is for the purpose of describing particular embodiments only and is not intended to be limiting of the invention. For example, as used herein, the singular forms “a”, “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. As used herein, the term “and/or” includes any and all combinations of one or more of the associated listed items and may be abbreviated as “/”.

Spatially relative terms, such as “under”, “below”, “lower”, “over”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements described as “under”, or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly. Similarly, the terms “upwardly”, “downwardly”, “vertical”, “horizontal” and the like are used herein for the purpose of explanation only unless specifically indicated otherwise.

Although the terms “first” and “second” may be used herein to describe various features/elements (including steps), these features/elements should not be limited by these terms, unless the context indicates otherwise. These terms may be used to distinguish one feature/element from another feature/element. Thus, a first feature/element discussed below could be termed a second feature/element, and similarly, a second feature/element discussed below could be termed a first feature/element without departing from the teachings of the present invention.

In general, any of the apparatuses and methods described herein should be understood to be inclusive, but all or a sub-set of the components and/or steps may alternatively be exclusive and may be expressed as “consisting of” or alternatively “consisting essentially of” the various components, steps, sub-components or sub-steps.

As used herein in the specification and claims, including as used in the examples and unless otherwise expressly specified, all numbers may be read as if prefaced by the word “about” or “approximately,” even if the term does not expressly appear. The phrase “about” or “approximately” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), etc. Any numerical values given herein should also be understood to include about or approximately that value, unless the context indicates otherwise. For example, if the value “10” is disclosed, then “about 10” is also disclosed. Any numerical range recited herein is intended to include all sub-ranges subsumed therein. It is also understood that when a value is disclosed that “less than or equal to” the value, “greater than or equal to the value” and possible ranges between values are also disclosed, as appropriately understood by the skilled artisan. For example, if the value “X” is disclosed the “less than or equal to X” as well as “greater than or equal to X” (e.g., where X is a numerical value) is also disclosed. It is also understood that the throughout the application, data is provided in a number of different formats, and that this data, represents endpoints and starting points, and ranges for any combination of the data points. For example, if a particular data point “10” and a particular data point “15” are disclosed, it is understood that greater than, greater than or equal to, less than, less than or equal to, and equal to 10 and 15 are considered disclosed as well as between 10 and 15. It is also understood that each unit between two particular units are also disclosed. For example, if 10 and 15 are disclosed, then 11, 12, 13, and 14 are also disclosed.

Although various illustrative embodiments are described above, any of a number of changes may be made to various embodiments without departing from the scope of the invention as described by the claims. Optional features of various device and system embodiments may be included in some embodiments and not in others. Therefore, the foregoing description is provided primarily for exemplary purposes and should not be interpreted to limit the scope of the invention as it is set forth in the claims.

The examples and illustrations included herein show, by way of illustration and not of limitation, specific embodiments in which the subject matter may be practiced. As mentioned, other embodiments may be utilized and derived there from, such that structural and logical substitutions and changes may be made without departing from the scope of this disclosure. Such embodiments of the inventive subject matter may be referred to herein individually or collectively by the term “invention” merely for convenience and without intending to voluntarily limit the scope of this application to any single invention or inventive concept, if more than one is, in fact, disclosed. Thus, although specific embodiments have been illustrated and described herein, any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

What is claimed is:

1. An acoustically driven ferromagnetic resonance (ADFMR) apparatus, comprising:
a substrate;
at least one input acoustic transducer on the substrate that is configured to activate the piezoelectric element to generate an acoustic wave;
a magnetostrictive material on the substrate, wherein the magnetostrictive material comprises a thin film of either iron-gallium-boron (Fe—Ga—B) or a stack of pairs of iron-gallium (Fe—Ga) and boron (B) layers and wherein the magnetostrictive material is configured to receive and absorb the acoustic wave based on a ferromagnetic resonance of the magnetostrictive material; and
at least one output acoustic transducer on the substrate;
a readout circuit to detect a change in the acoustic wave to measure an unknown magnetic field to which the magnetostrictive element is exposed.

2. The apparatus of claim 1, wherein the magnetostrictive layer comprises a homogenous layer of Fe—Ga—B.

3. The apparatus of claim 1, wherein the magnetostrictive layer comprises the stack of pairs of Fe—Ga and B layers.

4. The apparatus of claim 3, wherein the stack of pairs comprises between 2 and 30 pairs.

5. The apparatus of claim 3, wherein the stack of pairs comprises between 5 and 15 pairs.

6. The apparatus of claim 1, wherein the magnetostrictive layer is between 10-100 nm thick.

7. The apparatus of claim 1, wherein the magnetostrictive layer is between 10-30 nm thick.

8. The apparatus of claim 1, further comprising a radio-frequency voltage source electrically connected to the input acoustic transducer.

9. The apparatus of claim 1, wherein the acoustic wave resonates at a ferromagnetic resonance of the magnetostrictive material.

10. The apparatus of claim 1, wherein the readout circuit is configured to detect the change in the acoustic wave by detecting one of: an output voltage amplitude, a change in impedance, and/or a reflection of the acoustic wave in the magnetostrictive material.

11. The apparatus of claim 1, wherein the substrate comprises a piezoelectric substrate.

12. The apparatus of claim 1, wherein the substrate comprises lithium niobate (LiNbO3).

13. An acoustically driven ferromagnetic resonance (ADFMR) apparatus, comprising:
a piezoelectric substrate;
at least one input acoustic transducer on the piezoelectric substrate that is configured to activate the piezoelectric element to generate an acoustic wave;
a magnetostrictive material on the piezoelectric substrate, wherein the magnetostrictive material comprises a thin film of iron-gallium-boron (Fe—Ga—B) and wherein the magnetostrictive material is configured to receive and absorb the acoustic wave based on a ferromagnetic resonance of the magnetostrictive material;
at least one output acoustic transducer on the piezoelectric substrate;
a readout circuit to detect a change in the acoustic wave to measure an unknown magnetic field to which the magnetostrictive element is exposed.

14. An acoustically driven ferromagnetic resonance (ADFMR) apparatus, comprising:
a piezoelectric substrate;
at least one input acoustic transducer on the piezoelectric substrate that is configured to activate the piezoelectric element to generate an acoustic wave;
a magnetostrictive material on the piezoelectric substrate, wherein the magnetostrictive material comprises a multilayer stack comprising repeating pairs of iron-gallium (Fe—Ga) and boron (B) layers, and is configured to receive and absorb the acoustic wave based on a ferromagnetic resonance of the magnetostrictive material; and
at least one output acoustic transducer on the piezoelectric substrate;
a readout circuit to detect a change in the acoustic wave to measure an unknown magnetic field to which the magnetostrictive element is exposed.

15. A method of forming an acoustically driven ferromagnetic resonance (ADFMR) apparatus, the method comprising:
sputtering iron, gallium and boron (Fe—Ga—B) into a single layer of magnetostrictive material on a substrate;
forming at least one input acoustic transducer and at least one output acoustic transducer on the substrate between the magnetostrictive material;
coupling the at least one input acoustic transducer to an energy source configured to drive the at least one input acoustic transducer to apply an acoustic wave to the substrate; and
coupling the at least one output acoustic transducer to a readout circuit configured to detect a change in the acoustic wave through the substrate to measure an unknown magnetic field to which the magnetostrictive element is exposed.

16. The method of claim 15, wherein sputtering Fe—Ga—B into a single layer of magnetostrictive material comprises sputtering to a thickness of between 10-100 nm.

17. The method of claim 15, wherein sputtering Fe—Ga—B into a single layer of magnetostrictive material comprises co-sputtering an iron-gallium (Fe—Ga) sputter target and a boron (B) sputter target.

18. The method of claim 15, wherein sputtering Fe—Ga—B into a single layer of magnetostrictive material comprises sputtering from a composite sputter target of Fe—Ga—B.

19. The method of claim 15, wherein sputtering on the substrate comprises sputtering onto a piezoelectric substrate.

20. The method of claim 15, wherein sputtering on the substrate comprises sputtering onto a lithium niobate (LiNbO3) substrate.

21. The method of claim 15, wherein the step of sputtering Fe—Ga—B into a single layer of magnetostrictive material occurs after forming the at least one input acoustic transducer.

22. A method of forming an acoustically driven ferromagnetic resonance (ADFMR) apparatus, the method comprising:
sputtering pairs of layers of iron-gallium (Fe—Ga) and boron (B) into a multilayer stack of magnetostrictive material on a piezoelectric substrate;
forming at least one input acoustic transducer and at least one output acoustic transducer on the piezoelectric substrate between the magnetostrictive material;
coupling the at least one input acoustic transducer to an energy source configured to drive the at least one input acoustic transducer to apply an acoustic wave to the piezoelectric substrate; and
coupling the at least one output acoustic transducer to a readout circuit configured to detect a change in the acoustic wave through the piezoelectric substrate to measure an unknown magnetic field to which the magnetostrictive element is exposed.

23. The method of claim 22, wherein sputtering pairs of layers of Fe—Ga and B into the multilayer stack of magnetostrictive material comprises forming the multilayer stack having a thickness of between 10-100 nm.

24. The method of claim 22, wherein sputtering pairs of layers of Fe—Ga and B into the multilayer stack of magnetostrictive material comprises alternating between sputtering an iron-gallium (Fe—Ga) sputter target and a boron (B) sputter target.

25. The method of claim 22, wherein sputtering pairs of layers of Fe—Ga and B into the multilayer stack of magnetostrictive material comprises sputtering between 5-30 pairs of layers of Fe—Ga and B.

26. The method of claim 22, wherein sputtering on the piezoelectric substrate comprises sputtering onto a lithium niobate (LiNbO3) substrate.

27. The method of claim 22, wherein the step of sputtering the pairs of layers of Fe—Ga and B into the multilayer stack of magnetostrictive material occurs after forming the at least one input acoustic transducer.
